(19) United States
(12) Patent Application Publication
(10) Pub. No.: US 2013/0168148 A1
(43) Pub. Date: Jul. 4, 2013

(54) MULTILAYER PRINTED WIRING BOARD AND METHOD OF MANUFACTURING SAME

(71) Applicants: Toshinobu Kanai, Osaka (JP); Ryuichi Saito, Mie (JP); Hideki Higashitani, Mie (JP)

(72) Inventors: Toshinobu Kanai, Osaka (JP); Ryuichi Saito, Mie (JP); Hideki Higashitani, Mie (JP)

(21) Appl. No.: 13/822,446

(22) PCT Filed: Nov. 24, 2011
(86) PCT No.: PCT/JP2011/006518

§ 371 Date: Mar. 12, 2013

(30) Foreign Application Priority Data
Dec. 6, 2010 (JP) 2010 271052
Dec. 6, 2010 (JP) 2010 271053

(51) Int. Cl. H05K 1/02

(52) U.S. Cl. CPC H05K 1/0298
USPC 174/262; 156/60; 156/247; 156/64

(57) ABSTRACT

A multilayer wiring board includes a double-sided wiring board, an insulating substrate stacked on the double-sided wiring board, vias provided in through-holes in the insulating substrate, an outermost wiring on an upper surface of the insulating substrate, a first fiducial mark provided on the double-sided wiring board, and a second fiducial mark provided on the insulating substrate. The first fiducial mark contains a wiring of the double-sided wiring board. The second fiducial mark contains at least one via out of the vias. The first and second fiducial marks are provided for positioning the double-sided wiring board and the insulating substrate to each other. This multilayer wiring board includes layers positioned precisely.

### TECHNICAL FIELD

The present invention relates to a multilayer wiring board including stacked wiring boards, and a method of manufacturing the multilayer wiring board.

### BACKGROUND ART

As electronic devices have become more compact and more densely packed in recent years, circuit boards have been strongly demanded to have a multilayered structure in a consumer market as well as in an industrial market.

In such wiring boards, it is essential to develop a method of interconnecting wiring circuit layers and also to develop a reliable structure of the wiring circuit layers. A method of manufacturing a high density multilayer wiring board by interconnecting wiring circuit layers via conductive paste is proposed.

FIGS. 7A to 7L are cross sectional views of a conventional multilayer wiring board for illustrating a method of manufacturing the wiring board. This wiring board has an IVH structure including layers all made of resin.

FIG. 7A shows insulating board 501.

As shown in FIG. 7B, protective films 502 are stacked on both sides of insulating board 501.

Then, as shown in FIG. 7C, through-holes 503 are formed by hole-machining, such as laser machining, so as to allow the holes to completely pass through insulating board 501 and protective films 502.

As shown in FIG. 7D, through-holes 503 are filled with conductive paste 504 as a conductive material. After that, as shown in FIG. 7E, protective films 502 are removed.

Then, as shown in FIG. 7F, wiring materials 505 as foil are stacked on both sides of insulating board 501.

Then, as shown in FIG. 7G, insulating board 501 with wiring materials 505 formed thereon is heated and pressed to bond wiring materials 505 to insulating board 501. The heat-and-pressure process thermally hardens conductive paste 504 electrically connected to wiring materials 505.

Then, as shown in FIG. 7H, wiring materials 505 are etched to form circuits, thereby providing double-sided wiring board 507 having wirings 506.

Then, as shown in FIG. 7I, insulating substrates 509 and wiring materials 510 are stacked on both sides of double-sided wiring board 507. Insulating substrates 509 include conductive paste 508 and are formed by the same processes shown in FIGS. 7A to 7E.

Then as shown in FIG. 7J, insulating substrates 509 with wiring materials 510 formed thereon are heated and pressed to bond wiring materials 510 to insulating substrates 509. At this moment, double-sided wiring board 507 is bonded to insulating substrates 509.

The heating and pressing process thermally hardens conductive paste 508 similarly to shown in FIG. 7G. This process allows wiring materials 510 to contact double-sided wiring board 507 securely, thereby establishing an electrical connection via conductive paste 508.

Then, as shown in FIG. 7K, wiring materials 510 on the outermost layers are etched to form circuits, thereby providing multilayer wiring board 512 having wirings 511. Multilayer wiring board 512 shown in FIG. 7K has four layers, but the number is not limited to four. As shown in FIG. 7L, a ten-layered wiring board having wirings 513 can be obtained as another multilayer wiring board 514 by repeating the same processes as described above.

Multilayer wiring boards similar to conventional multilayer wiring board 514 are shown in Patent Literatures 1 and 2.

In the heating and pressing process shown in FIG. 7G to prepare the multilayer wiring board, a thermosetting resin contained in insulating board 501 is hardened and shrinks. This generates internal stress, resulting in dimensional shrinkage in its surface directions.

When wiring materials 505 are partially etched, as shown in FIG. 7H, a part of the internal stress is released, thereby increasing the dimension in the surface directions. However, some residual stress remains and accumulates in insulating board 501 while the heating and pressing process and the circuit-forming process are repetitively executed. Thus, a large number of layers of multilayer wiring board 514 increases a variation of the positions of wirings 513 of the outermost layers.

In the conventional method of manufacturing a multilayer wiring board shown in FIGS. 7A to 7L, the heating and pressing process and the circuit-forming process are repetitively executed by a predetermined number of times according to the number of layers of multilayer wiring board 514, accordingly increases its manufacturing time.

Plural double-sided wiring boards 507 and plural insulating substrates 509 for connection are stacked alternately, and wiring materials 510 are further stacked thereon at once. Next, they are temporarily fixed to each other to form a laminated body. The laminated body is then heated and pressed, thereby manufacturing the multilayer wiring board in a shorter time. The temporary fixation prevents misalignment between the double-sided wiring boards, the insulating substrates for connection, and the wiring materials during handling before heating and pressing.

One possible method for the temporary fixation is to partially weld the plurality of insulating substrates 509 to each other by using heating tools after completion of stacking. According to this method, the laminated body is partially subjected to heat and pressure so that insulating substrates 509 are partially welded and fixedly positioned with wiring materials 510 and double-sided wiring board 507 formed on both sides of each insulating substrate 509.

However, the required heat capacity of a laminated body increases with increasing number of layers of the multilayer wiring board. This possibly prevents those insulating substrates for connection from being fully bonded to those double-sided wiring boards which are away from the heating tools.

Multilayer wiring boards can be prepared productively by heating and pressing laminated bodies sandwiched between rigid plate materials, such as SUS plates.

However, when a number of laminated bodies are stacked, it may be difficult to press them uniformly in a heat-and-pressure process. Specifically, the laminated bodies differ in thickness between some regions having wirings and vias, and other regions not having wirings or vias. If the laminated bodies are pressed in this state, the pressure may not be applied to the regions not having wirings or vias.

This problem is particularly noticeable when laminated bodies, each of which is formed by one batch lamination process, are stacked on each other in order to increase productivity. More specifically, the boards have voids due to the lack of resin embedment and these voids are very difficult to be recognized by appearance.

### CITATION LIST

### Patent Literature

Patent Literature 1: Japanese Patent Laid-Open Publication No. 2000-13023
Patent Literature 2: Japanese Patent Laid-Open Publication No. 2004-265890

### SUMMARY

A multilayer wiring board includes a double-sided wiring board, an insulating substrate stacked on the double-sided wiring board, vias provided in through-holes in the insulating substrate, an outermost wiring on an upper surface of the insulating substrate, a first fiducial mark provided on the double-sided wiring board, and a second fiducial mark provided on the insulating substrate. The first fiducial mark contains a wiring of the double-sided wiring board. The second fiducial mark contains at least one via out of the vias. The first and second fiducial marks are provided for positioning the double-sided wiring board and the insulating substrate to each other.

This multilayer wiring board includes layers positioned precisely.

### BRIEF DESCRIPTION OF DRAWINGS

FIG. 1A is a sectional view of a multilayer wiring board according to an exemplary embodiment of the present invention.

FIG. 1B is a partial enlarged sectional view of the multilayer wiring board shown in FIG. 1A.

FIG. 2A is a sectional view of the multilayer wiring board according to the embodiment for illustrating a method of manufacturing the multilayer wiring board.

FIG. 2B is a sectional view of the multilayer wiring board according to the embodiment for illustrating the method of manufacturing the multilayer wiring board.

FIG. 2C is a sectional view of the multilayer wiring board according to the embodiment for illustrating the method of manufacturing the multilayer wiring board.

FIG. 2D is a sectional view of the multilayer wiring board according to the embodiment for illustrating the method of manufacturing the multilayer wiring board.

FIG. 2E is a sectional view of the multilayer wiring board according to the embodiment for illustrating the method of manufacturing the multilayer wiring board.

FIG. 2F is a sectional view of the multilayer wiring board according to the embodiment for illustrating the method of manufacturing the multilayer wiring board.

FIG. 2G is a sectional view of the multilayer wiring board according to the embodiment for illustrating the method of manufacturing the multilayer wiring board.

FIG. 2H is a sectional view of the multilayer wiring board according to the embodiment for illustrating the method of manufacturing the multilayer wiring board.

FIG. 2I is a sectional view of the multilayer wiring board according to the embodiment for illustrating the method of manufacturing the multilayer wiring board.

FIG. 2J is a sectional view of the multilayer wiring board according to the embodiment for illustrating the method of manufacturing the multilayer wiring board.

FIG. 2K is a sectional view of the multilayer wiring board according to the embodiment for illustrating the method of manufacturing the multilayer wiring board.

FIG. 3A is a sectional view of the multilayer wiring board according to the embodiment for illustrating the method of manufacturing the multilayer wiring board.

FIG. 3B is a plan view of a fiducial mark of the multilayer wiring board according to the embodiment.

FIG. 3C is a plan view of another fiducial mark of the multilayer wiring board according to the embodiment.

FIG. 3D is a plan view of still another fiducial mark of the multilayer wiring board according to the embodiment.

FIG. 3E is a plan view of a further fiducial mark of the multilayer wiring board according to the embodiment.

FIG. 3F is a plan view of a further fiducial mark of the multilayer wiring board according to the exemplary embodiment.

FIG. 3G is a plan view of the fiducial marks of the multilayer wiring board according to the embodiment.

FIG. 4A is a sectional view of the multilayer wiring board according to the embodiment for illustrating the method of manufacturing the multilayer wiring board.

FIG. 4B is a sectional view of the multilayer wiring board according to the embodiment for illustrating the method of manufacturing the multilayer wiring board.

FIG. 4C is a sectional view of the multilayer wiring board according to the exemplary embodiment for illustrating the method of manufacturing the multilayer wiring board.

FIG. 4D is a top view of the multilayer wiring board shown in FIG. 4A.

FIG. 5A is a sectional view of the multilayer wiring board according to the embodiment for illustrating another method of manufacturing the multilayer.

FIG. 5B is a sectional view of the multilayer wiring board according to the embodiment for illustrating the method of manufacturing the multilayer wiring board.

FIG. 5C is a sectional view of the multilayer wiring board according to the embodiment for illustrating the method of manufacturing the multilayer wiring board.

FIG. 5D is a sectional view of the multilayer wiring board according to the embodiment for illustrating the method of manufacturing the multilayer wiring board.

FIG. 6A is a top view of a test coupon of the multilayer wiring board according to the embodiment.

FIG. 6B is a sectional view of the multilayer wiring board at line 6B-6B shown in FIG. 6A.

FIG. 6C is a sectional view of another test coupon of the multilayer wiring board according to the embodiment.

FIG. 7A is a sectional view of a conventional multilayer wiring board for illustrating a method of manufacturing the conventional multilayer wiring board.

FIG. 7B is a sectional view of the conventional multilayer wiring board for illustrating the method of manufacturing the conventional multilayer wiring board.

FIG. 7C is a sectional view of the conventional multilayer wiring board for illustrating the method of manufacturing the conventional multilayer wiring board.

FIG. 7D is a sectional view of the conventional multilayer wiring board for illustrating the method of manufacturing the conventional multilayer wiring board.

FIG. 7E is a sectional view of the conventional multilayer wiring board for illustrating the method of manufacturing the conventional multilayer wiring board.

FIG. 7F is a sectional view of the conventional multilayer wiring board for illustrating the method of manufacturing the conventional multilayer wiring board.

FIG. 7G is a sectional view of the conventional multilayer wiring board for illustrating the method of manufacturing the conventional multilayer wiring board.

FIG. 7H is a sectional view of the conventional multilayer wiring board for illustrating the method of manufacturing the conventional multilayer wiring board.

FIG. 7I is a sectional view of the conventional multilayer wiring board for illustrating the method of manufacturing the conventional multilayer wiring board.

FIG. 7J is a sectional view of the conventional multilayer wiring board for illustrating the method of manufacturing the conventional multilayer wiring board.

FIG. 7K is a sectional view of the conventional multilayer wiring board for illustrating the method of manufacturing the conventional multilayer wiring board.

FIG. 7L is a sectional view of the conventional multilayer wiring board for illustrating the method of manufacturing the conventional multilayer wiring board.

### DETAIL DESCRIPTION OF PREFERRED EMBODIMENT

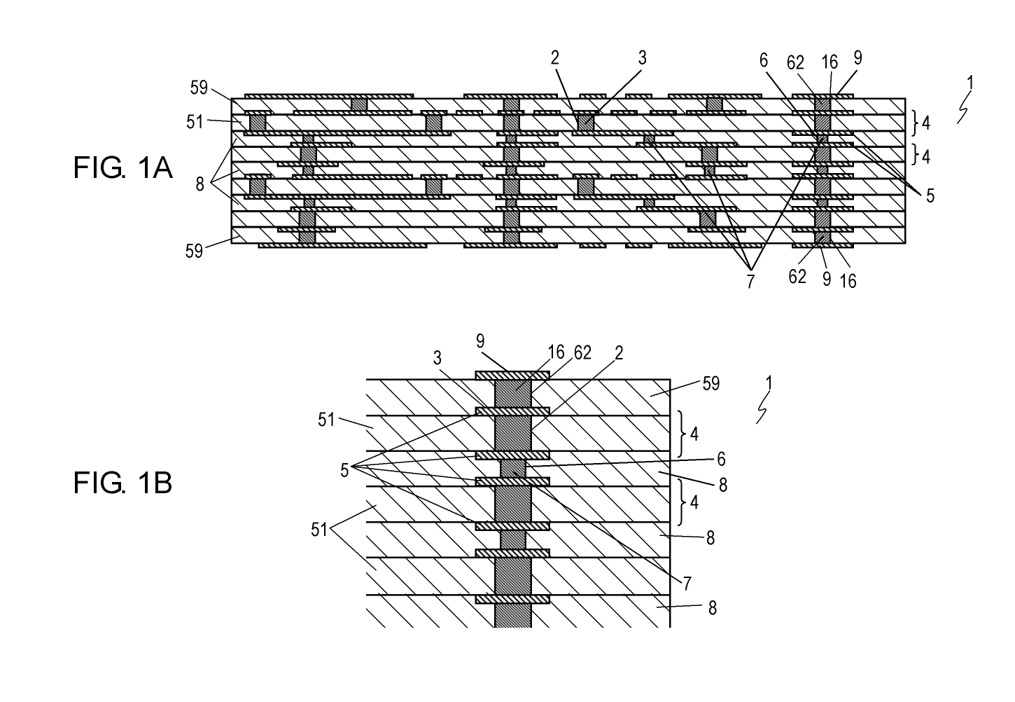

FIG. 1A is a sectional view of multilayer wiring board 1 according to an exemplary embodiment of the present invention. Multilayer wiring board 1 includes double-sided wiring boards 4, insulating substrates 8 for connection, insulating substrates 59 for connection, outermost wirings 9, and vias 7. Vias 7 are made of conductive paste. Insulating substrates 8 for connection and double-sided wiring boards 4 are alternately stacked on each other. Insulating substrates 59 for connection are stacked as the outermost layers on the outside surfaces of the outermost ones of double-sided wiring boards 4. Outermost wirings 9 are stacked on the outside surfaces of insulating substrates 59 for connection. Each of double-sided wiring boards 4 includes insulating board 51, through-holes 2 perforated in insulating board 51, vias 3 made of conductive paste filling through-holes 2, and wirings 5 made of conductive foils provided on both surfaces of insulating board 51. Vias 3 contact and are connected with wirings 5 provided on both surfaces of insulating board 51. Each of insulating substrates 8 for connection has through-holes 6 therein, which are filled with the conductive paste for forming vias 7. Via 7 contacts wirings 5 of two double-sided wiring boards 4. The conductive paste filling through-holes 6 to constitute vias 7 is compressed from both sides thereof with wirings 5 of two double-sided wiring boards 4, thereby being connected with wirings 5. Similarly, insulating substrates 59 for connection have through-holes 62 therein, which are filled with the conductive paste for forming vias 16. Via 16 contacts and is connected with outermost wiring 9 and wiring 5 of double-sided wiring board 4.

Insulating substrates 8 and 59 for connection shown in FIG. 1A have not only through-holes 2 and 62 to provide electrical connection but also after-mentioned through-holes for fiducial marks which are filled with conductive paste.

FIG. 1B is a partial enlarged sectional view of multilayer wiring board 1 shown in FIG. 1A. The wirings 5 provided on both sides of each via 7 are provided on both surfaces of double-sided wiring board 4, and project from both surfaces of insulating board 51 of each double-sided wiring board 4. These wirings 5 are embedded in insulating substrates 8 for connection at both ends of each via 7 so as to securely compress via 7. This structure connects vias 7 electrically with wirings 5 stably, and allows through-holes 6 to have a small diameter.

Double-sided wiring board 4 is manufactured by a single heating and pressing process and a single circuit-forming process. These processes reduce positional variations of wirings 5 which are caused by variations in residual stress, thus positioning wirings 5 with respect to vias 7 precisely.

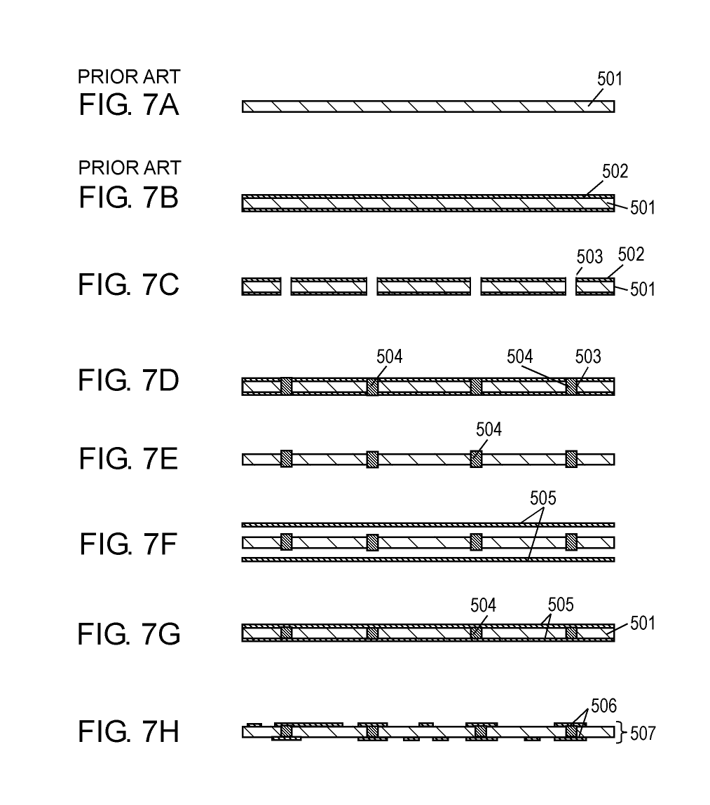

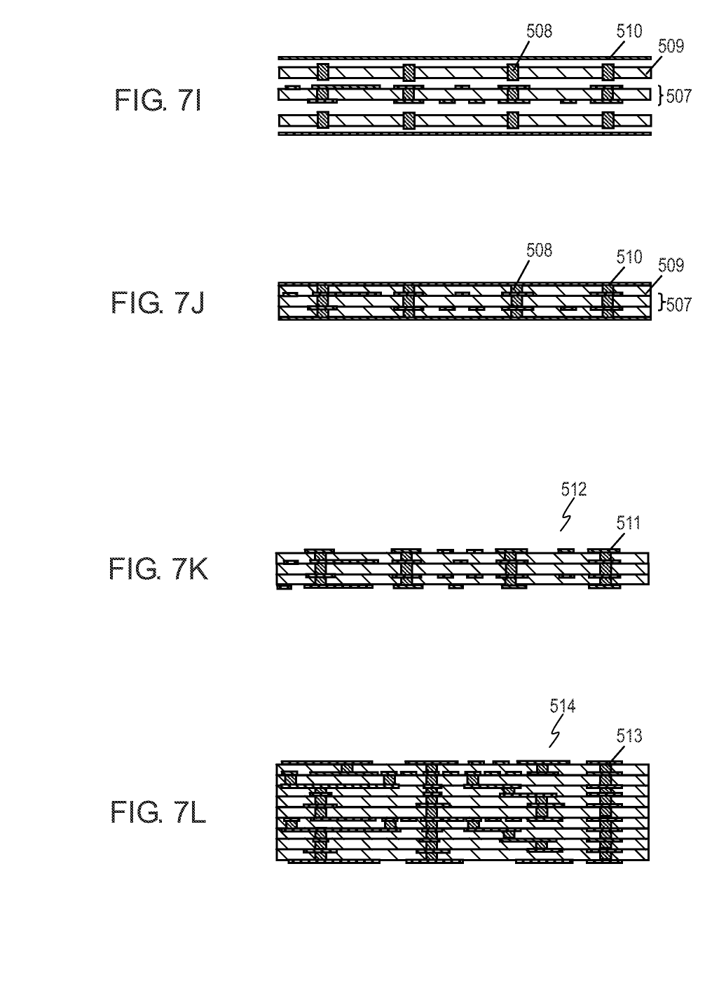

Wiring board 1 having ten layers is manufactured by two heating and pressing processes and a single circuit-forming process. These processes reduce the residual stress, accordingly positioning outermost wirings 9 more precisely than wirings 513 of the outermost layers of conventional multilayer wiring board 514 shown in FIG. 7L. Thus, in multilayer wiring board 1 according to the embodiment, outermost wirings 9 have small positional variations, and consequently, have a positioning precision close to the design value. This reduces the tolerance of misalignment between the solder mask and outermost wirings 9.

In multilayer wiring board 1, outermost wirings 9 precisely positioned facilitate the positioning between wirings 9 and IC chips via solder bumps in bare chip mounting or anisotropically-conductive film (ACF) mounting. Thus, the IC chips are easily mounted on multilayer wiring board 1.

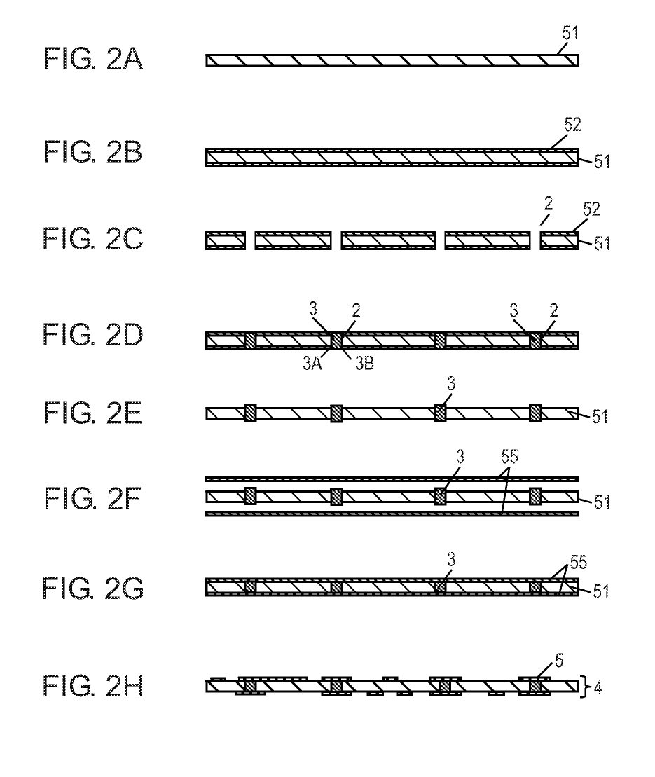

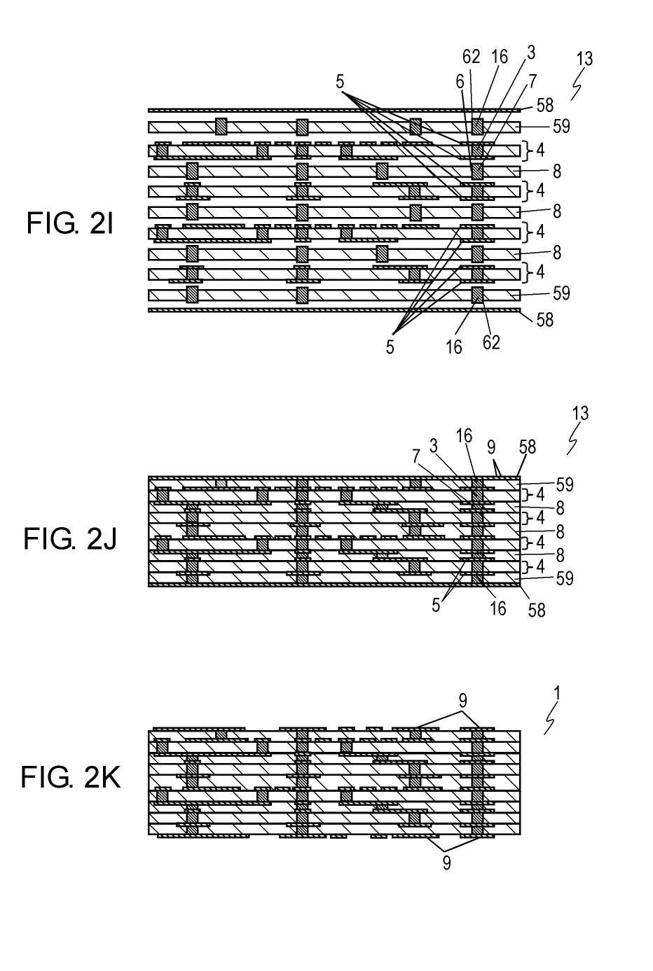

A method of manufacturing multilayer wiring board 1 will be described below. FIGS. 2A to 2K are sectional views of multilayer wiring board 1 for illustrating the method of manufacturing multilayer wiring board 1.

FIG. 2A shows insulating board 51. As shown in FIG. 2B, protective films 52 are stuck onto both surfaces of insulating board 51.

Insulating board 51 is made of a composite material composed of fiber and resin. The composite material can be formed, for example, by impregnating fiber, such as glass fiber or organic fiber, with resin, such as epoxy resin, polyimide resin, bismaleimide triazine (BT) resin, polyphenylene ether (PPE) resin, or polyphenylene oxide (PPO) resin. The composite material can alternatively be formed by impregnating porous film, such as polyimide film, aramid film, polytetrafluoroethylene (PTFE) film, or liquid crystal polymer (LCP) film, with resin, such as epoxy resin, polyimide resin, BT resin, PPE resin, or PPO resin. The composite material can further alternatively be formed by applying adhesive to both surfaces of a polyimide film, an aramid film, or an LCP film.

The resin, being a thermosetting-type resin allows multilayer wiring board 1 to be shaped easily.

Insulating board 51 may preferably be a porous compressible board. The porous compressible board can be compressed when pressed in its thickness direction. The degree of compression can be adjusted by controlling pores in the porous board or insulating board 51.

Insulating board 51 as a porous board can alternatively be formed by impregnating fiber paper, such as a woven or nonwoven fabric, with one of the above-mentioned resins. The pores can be formed simultaneously to the impregnation. Nonwoven paper mainly made of aramid resin as the fiber paper and thermosetting resin mainly made of epoxy as the resin can form the pores in insulating board 51 uniformly and efficiently, thereby providing insulating board 51 highly compressible.

The thickness of insulating board 51 can range from 20 to 200 μm by adjusting the amount of fiber.

Protective films 52 mainly made of polyethylene terephthalate (PET) or polyethylene naphthalate (PEN), can be stuck onto both surfaces of insulating board 51 easily and productively.

As shown in FIG. 2C, through-holes 2 are formed by hole-machining, such as punching, drilling, or laser machining, to completely penetrate insulating board 51 and protective films 52. Laser machining, such as carbon dioxide laser or YAG laser, allows through-holes 2 with small diameters to be formed productively in a short time.

Carbon dioxide laser can form through-holes 2 having a diameter of 100 μm perforated in insulating board 51 having a thickness of 80 μm. A third harmonic of YAG laser can form through-holes 2 having a diameter of 30 μm perforated in insulating board 51 having a thickness of 30 μm.

Then, as shown in FIG. 2D, conductive paste 204 as a conductive material fills through-holes 2 to form vias 3. Via 3 contains resin 3A and conductive particles 3B dispersed in resin 3A. Conductive particles 3B are made of metal, such as copper or silver. Conductive particles 3B has preferably a substantially spherical shape so that the conductive paste for forming vias 3 can have a low viscosity even if conductive particles 3B are contained at a high rate.

In the processes shown in FIGS. 2C and 2D, not only through-holes 2 to provide electrical continuity but also through-holes 2 for fiducial marks are perforated in insulating board 51, and are filled with the conductive paste.

Conductive particles 3B made of metal contained in vias 3 may be melted and alloyed in a heat-and-pressure process to provide highly-reliable electrical connection. Such conductive particles can be made of a low-melting-point metal, such as tin. More specifically, the conductive particles can be made by adding a metal, such as silver or bismuth, to the low-melting-point metal by alloying either silver or bismuth with the low-melting-point metal or by coating the conductive particles, such as copper, with the low-melting-point metal on the surfaces of the conductive particles.

Then, as shown in FIG. 2E, protective films 52 are removed from insulating board 51. Protective films 52 secure a sufficient amount of the conductive paste filling for forming vias 3. Specifically, the conductive paste for forming vias 3 projects from the surfaces of insulating board 51 by a height substantially equal to the thickness of protective film 52. The thickness of protective film 52 may range preferably from 5% to 25% of the diameter of through-hole 2 so as to reduce the amount of the conductive paste attached to protective films 52 when protective film 52 is removed from insulating board 51.

Then, as shown in FIG. 2F, wiring materials 55, conductive foil, are stacked one on both surfaces of insulating board 51.

Then, as shown in FIG. 2G, insulating board 51 with wiring materials 55 of foil stacked thereon is heated and pressed to cause wiring materials 55 to adhere onto insulating board 51. After the filling of the conductive paste for forming vias 3 and before the heating and pressing process starts, a large amount of resin exists between the conductive particles, hence preventing the conductive particles from being electrically connected with each other. The heating and pressing process compresses vias 3, and thereby, causes the conductive particles to contact each other, accordingly establishing an electrical connection between the articles. The heating and pressing process causes wiring materials 55 to contact vias 3, thereby establishing an electrical connection between wiring materials 55 on both surfaces through vias 3.

In the case that vias 3 contains conductive metal particles that can be melted and alloyed in the heat-and-pressure process, alloy layers are formed between the conductive particles and between wiring materials 55 and conductive particles 3B during the heating and pressing process. As a result, the electrical connection between wiring materials 55 and vias 3 becomes more reliable.

Wiring material 55 according to the embodiment is an electrolytic copper foil having a thickness of 9 μm, but the thickness is not limited to this size. In order to reduce the thickness of multilayer wiring board 1, wiring material 55 can be made of an electrolytic copper foil having a thickness of 5 μm with a carrier, or a rolled copper foil having a thickness of 5 μm.

In the case that wiring material 55 is double-sided roughened foil made by electroplating both surfaces of a foil, wiring materials 55 has surfaces having pits like octopus traps therein, and are firmly bonded to insulating board 51.

Alternatively, only one surface of wiring material 55 to which insulating board 51 is attached may be roughened while the other surface of wiring material 55 to which insulating board 51 is not attached may not be roughened. In this case, the other surface to which insulating board 51 is not attached may be subjected to a chemical treatment, such as etching, after the heating and pressing process so as to form small asperities therein. This method enables wiring materials 55 to be etched uniformly so as to be thinner after being attached to insulating board 51, hence allowing wiring materials 55 to be patterned into fine wirings 5.

Then, as shown in FIG. 2H, wiring materials 55 are etched and patterned to from circuits, thereby providing double-sided wiring board 4 including wirings 5. Double-sided wiring board 4 is formed by a single heating and pressing process and a single circuit-forming process, and therefore reduces positional variations of wirings 5 caused by residual stress. Wiring materials 55 can be patterned by a photoresist method using a pattern film, but are preferably laser drawn, for example, by using a semiconductor laser. This can position wirings 5 more precisely.

Then, in a process shown in FIG. 2H, not only wiring materials 55 for forming wirings 5, but also after-mentioned fiducial marks are etched.

Then, as shown in FIG. 2I, outermost wiring materials 58, insulating substrates 8 and 59 for connection, and double-sided wiring boards 4 are stacked to provide laminated body 13. Insulating substrates 8 and 59 for connection have the same configuration as insulating board 51 formed by the processes shown in FIGS. 2A to 2E in which through-holes 2 are filled with the conductive paste. Insulating substrates 8 for connection have through-holes 6 filled with the conductive paste for forming vias 7, the conductive paste being the same as the conductive paste for forming vias 3. Insulating substrates 59 have through-holes 62 filled with conductive paste for forming vias 16, the conductive paste being the same as the conductive paste for forming vias 3. Wirings 5 of double-sided wiring boards 4 have small positional variations. The positions of wirings 5 are previously measured, and the measurement results are used to correct the positions of through-holes 6 and 62 of insulating substrates 8 and 59 for connection, thereby positioning through-holes 6 and 62 with respect to wirings 5 precisely.

Alternatively, insulating substrates 8 and 59 for connection can be classified according to the measurement results of the positions of wirings 5. Insulating substrates 8 and 59 for connection, and double-sided wiring boards 4 having wirings 5 and through-holes 2 and 62 aligned with each other can be selected to be stacked on each other. This process provides multilayer wiring board 1 including wirings 5 aligned precisely with through-holes 2 and 62 filled with the conductive paste for forming vias 7 and 16.

Wirings 5 projecting from insulating boards 51 of double-sided wiring boards 4 can effectively compress vias 7 of insulating substrates 8 for connection. This configuration connects vias 7 electrically with wirings 5 stably, thereby allowing through-holes 6 to have a smaller diameter.

In order to electrically connect vias 7 and 16 with wirings 5 stably, at least one of wirings 5 contacting and being connected with both side of each via 7 has a large thickness. Alternatively, protective films, which are the same as protective films 52 shown in FIG. 2B, used for forming insulating substrates 8 and 59 for connection have a large thickness so that vias 7 and 16 can project higher from insulating substrates 8 and 59 for connection, thereby connecting vias 7 and 16 with wirings 5.

In order to achieve more stable electrical connection, the conductive paste for forming vias 3, 7 and 16 may preferably contain conductive particles that can melt in the heating and pressing process. Insulating substrates 8 for connection need to be embedded with larger wirings 5 than insulating substrates 59 for connection does, and hence, preferably contains a larger amount of resin or have a more fluid resin at high temperatures than insulating substrates 59 for connection. An increase in the content or fluidity of the resin disrupts the electrical connection of the conductive paste upon being compressed. However, in multilayer wiring board 1 according to the embodiment, wirings 5 are embedded in insulating substrates 8 for connection from both ends of through-holes 6, and vias 7 are compressed more strongly than vias 16, hence electrically connecting vias 7 with wirings 5 securely.

The content or fluidity of the resin in insulating substrates 8 and 59 for connection or the thickness of insulating substrates 8 and 59 for connection may be increased in order to improve the ease of embedding wirings 5. In such cases, through-holes 6 and 62 may have larger diameters than through-holes 2 formed in double-sided wiring boards 4 so that vias 7 and 16 formed in through-holes 6 and 62 can provide high connection reliability.

In other cases, the diameters of through-holes 6 and 62 formed in insulating substrates 8 and 59 for connection can be larger than those of through-holes 2 formed in double-sided wiring boards 4.

The thicknesses of wirings 5 at layers may not necessarily be the identical to each other. The thicknesses of wirings 5 may be determined according to the function of each layer. For example, to make fine wirings, the thickness can be thin, whereas, to reduce the impedance for secure grounding, the thickness can be thick.

Furthermore, the thickness of wirings 5 can be changed according to the design pattern or the fluidity of the resin, thereby improving the stability of molding the resin in the heating and pressing process.

To obtain a high yield of finished products, double-sided wiring boards 4 which were found by testing to have short-circuit or breakage defect of wirings 5 may be replaced by other double-sided wiring boards 4 having no defect.

Then, as shown in FIG. 2J, outermost wiring materials 58 are bonded to insulating substrates 59 for connection by heating and pressing laminated body 13. At this moment, double-sided wiring boards 4 are bonded to insulating substrates 8 and 59 for connection. This heating and pressing process compresses and thermally hardens vias 7 and 16 similarly to the process shown in FIG. 2G. This process causes double-sided wiring boards 4 electrically contact each other through vias 7, and also causes double-sided wiring boards 4 to securely contact outermost wiring materials 58 through vias 16, thereby establishing an electrical connection.

Outermost wiring materials 58 are etched to form circuits, thereby providing wiring board 1 having ten layers including outermost wirings 9, as shown in FIG. 2K.

Outermost wiring materials 58 can be patterned by a photoresist method using a pattern film, but are preferably laser drawn, for example, by using a semiconductor laser. This provides wirings 9 with precise positions. Wiring board 1 having ten layers is formed by two heating and pressing process and a single circuit-forming process as described above. For this reason, in multilayer wiring board 1 according to the embodiment, the positional variations of outermost wirings 9, which are caused by variations in residual stress, are small. As a result, outermost wirings 9 can have higher positioning precision than wirings 513 of conventional multilayer wiring board 514 shown in FIG. 7L.

Multilayer wiring board 1 according to the embodiment has ten layers, but the number of layers is not limited to ten. Multilayer wiring board 1 can have, for example, 6, 8, 10, or 12 layers by changing the number of double-sided wiring boards 4 and insulating substrates 8 for connection to be alternately stacked, as shown in FIG. 2I.

The manufacturing method according to the embodiment shown in FIGS. 2A to 2K allows multilayer wiring board 1 to be manufactured by two heating and pressing process and a single circuit-forming process regardless of the number of layers of double-sided wiring boards 4 and insulating substrates 8 for connection. As a result, a multilayer wiring board having a large number of layers can be manufactured productively.

In laminated body 13 shown in FIG. 2I, when its layers (double-sided wiring boards 4 and insulating substrates 8 and 59 for connection) are stacked on each other, the layers are preferably aligned using fiducial marks formed in the layers, and then, are temporarily fixed. The fiducial marks will be described as follows.

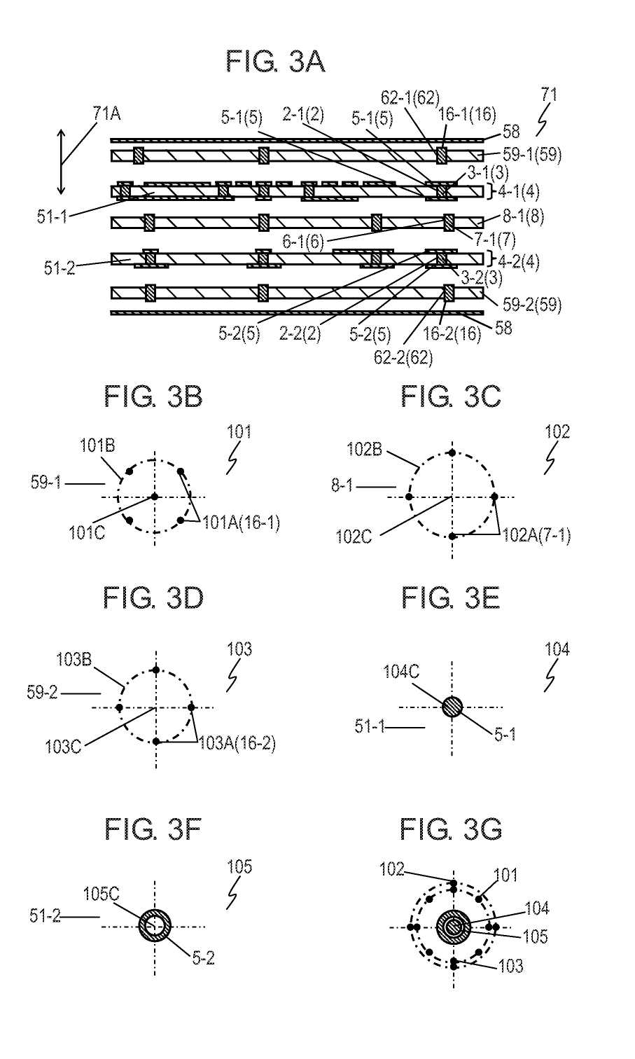

FIG. 3A is a sectional view of the multilayer wiring board according to the embodiment for illustrating a method of manufacturing the multilayer wiring board. Specifically, FIG. 3A is a sectional view of another laminated body 71 according to the embodiment and shows the fiducial marks. In FIG. 3A, components identical to those of laminated body 13 shown in FIG. 2I are denoted by the same reference numerals. Laminated body 71 includes double-sided wiring boards 4-1 and 4-2 similar to double-sided wiring boards 4 of laminated body 13, insulating substrate 8-1 for connection similar to insulating substrates 8 for connection of laminated body 13, insulating substrates 59-1 and 59-2 for connection similar to insulating substrates 59 of laminated body 13, and outermost wiring materials 58. Insulating substrates 8-1, 59-1, and 59-2 for connection have through-holes 6-1, 62-1, and 62-2, respectively, which are similar to through-holes 6 and 62 of insulating substrates 8 and 59 for connection of laminated body 13. Through-holes 6-1, 62-1, and 62-2 are filled with conductive paste for forming vias 7-1, 16-1, and 16-2, the conductive paste being the same as the conductive paste for forming vias 7 and 16 of laminated body 13. Double-sided wiring boards 4-1 and 4-2 have wirings 5-1 and 5-2, respectively, which are similar to wirings 5 provided on double-sided wiring boards 4 of laminated body 13. Double-sided wiring boards 4-1 and 4-2 includes insulating boards 51-1 and 51-2, respectively, which are similar to insulating board 51 of double-sided wiring boards 4 of laminated body 13. In double-sided wiring boards 4-1 and 4-2, insulating boards 51-1 and 51-2 have through-holes 2-1 and 2-2, respectively, which are similar to through-holes 2 of double-sided wiring boards 4 of laminated body 13. Through-holes 2-1 and 2-2 are filled with conductive paste for forming vias 3-1 and 3-1, the conductive paste being the same as the conductive paste for forming vias 3 of double-sided wiring boards 4 of laminated body 13. Thus, outermost wiring material 58, insulating substrate 59-1 for connection, double-sided wiring board 4-1, insulating substrate 8-1 for connection, double-sided wiring board 4-2, insulating substrate 59-2 for connection, and outermost wiring material 58 are stacked in this order in lamination direction 71A. Laminated body 71 is heated and pressed to obtain a wiring board having six layers. The fiducial marks are preferably formed so as to recognize and detect misalignment of the stacked layers from a narrow field of view during stacking.

FIG. 3B is a plan view of fiducial mark 101 formed in insulating substrate 59-1 for connection viewing in lamination direction 71A. Fiducial mark 101 includes vias 101A implemented by vias 16-1. Vias 101A are arranged on a single circle 101B. The position of a fiducial mark implemented by only one via may not be recognized accurately enough, for example, due to variations in machining position. The position of fiducial mark 101 can be accurately recognized by recognizing center 101C of circle 101B or of fiducial mark 101 by image recognition or other methods based on vias 101A arranged on circle 101B shown in FIG. 3B according to the embodiment.

FIG. 3C is a plan view of fiducial mark 102 provided on insulating substrate 8-1 for connection viewing in lamination direction 71A. Fiducial mark 102 includes vias 102A implemented by vias 7-1. Vias 102A are arranged on a single circle 102B. The position of a fiducial mark implemented by a single via may not be recognized accurately enough, for example, due to variations in machining position. The position of fiducial mark 102 can be accurately recognized by recognizing center 102C of circle 102B or of fiducial mark 102 by image recognition or other methods based on vias 102A arranged on circle 102B shown in FIG. 3C according to the embodiment.

FIG. 3D is a plan view of fiducial mark 103 provided on insulating substrate 59-2 for connection viewing in lamination direction 71A. Fiducial mark 103 includes vias 103A implemented by vias 16-2. Vias 103A are arranged on a single circle 103B. The position of a fiducial mark having a single via may not be recognized accurately enough for example, due to variations in machining position. The position of fiducial mark 103 can be accurately recognized by recognizing center 103C of circle 103B or of fiducial mark 103 by image recognition or other methods based on vias 103A arranged on circle 103B shown in FIG. 3D according to the embodiment.

Fiducial marks 101 to 103 are formed so that centers 101C to 103C may be aligned viewing in lamination direction 71A while insulating substrates 8, 59-1, and 59-2 for connection are properly stacked in laminated body 71 shown in FIG. 3A. Thus, circles 101B to 103B are concentric viewing in lamination direction 71A. Although circles 101B and 103B have the same diameter, vias 101A and 103A are formed in laminated body 71 so as not to overlap each other viewing in lamination direction 71A. Circles 101B and 102B have diameters smaller than, i.e., different from the diameter of circle 103B. Vias 101A to 103A do not overlap each other viewing in lamination direction 71A by allowing circles 101B and 102B to have diameters different from the diameter of circle 103B, or allowing vias 101A and 103A to deviate from each other. This arrangement allows the relative positional relationship between vias 101A-103A formed in insulating substrates 8-1, 59-1, and 59-2 for connection to be recognized. Centers 101C to 103C of fiducial marks 101 to 103 are detected by, e.g. image recognition. Then, insulating substrates 8-1, 59-1, and 59-2 for connection are positioned to align fiducial marks 101 to 103 with each other such that one mark is enclosed in another mark during stacking, thereby allowing insulating substrates 8-1, 59-1, and 59-2 for connection to be stacked precisely.

FIG. 3E is a plan view of fiducial mark 104 provided on double-sided wiring board 4-1 viewing in lamination direction 71A. Fiducial mark 104 is implemented by wirings 5-1 and has a circular shape with center 104C. Wirings 5-1 of double-sided wiring board 4-1 have as small positional variations as wiring 5 of double-sided wiring boards 4 shown in FIG. 2K. As a result, the position of fiducial mark 104 can be accurately recognized by recognizing center 104C of fiducial mark 104 by, e.g. image recognition.

FIG. 3F is a plan view of fiducial mark 105 provided on double-sided wiring board 4-2 viewing in lamination direction 71A. Fiducial mark 105 is implemented by wiring 5-2 and has a circular annular shape with center 105C. Wirings 5-2 of double-sided wiring board 4-2 have small positional variations similar to those of wirings 5 of double-sided wiring boards 4 shown in FIG. 2K. As a result, the position of fiducial mark 105 can be accurately recognized by recognizing center 105C of fiducial mark 105 by, e.g. image recognition.

Fiducial marks 104 and 105 are arranged such that centers 104C and 105C can be aligned viewing in lamination direction 71A while double-sided wiring boards 4-1 and 4-2 are properly stacked in laminated body 71 shown in FIG. 3A. Thus, fiducial marks 104 and 105 are concentric viewing in lamination direction 71A. The circular annular shape of fiducial mark 105 has an inner diameter and an outer diameter which are larger than the circular shape of fiducial mark 104. In other words, fiducial mark 105 has a space into which fiducial mark 104 can be fitted viewing in lamination direction 71A. As a result, fiducial marks 104 and 105 are formed in laminated body 71 so as not to overlap each other viewing in lamination direction 71A. Thus, centers 104C and 105C of fiducial marks 104 and 105 of double-sided wiring boards 4-1 and 4-2 are recognized by, e.g. image recognition. Then, double-sided wiring boards 4-1 and 4-2 are positioned such that fiducial mark 104 is fitted into fiducial mark 105 and that centers 104C and 105C are aligned with each other viewing in lamination direction 71A. This arrangement allows the relative positional relationship between wirings 5-1 and 5-2 formed on double-sided wiring boards 4-1 and 4-2 is identified. Double-sided wiring boards 4-1 and 4-2 are stacked such that centers 104C and 105C of fiducial marks 104 and 105 can be aligned with each other viewing in lamination direction 71A, thereby allowing double-sided wiring boards 4-1 and 4-2 to be stacked precisely.

FIG. 3G is a plan view of fiducial marks 101 to 105 of laminated body 71 viewing in lamination direction 71A. Fiducial marks 101 to 105 are arranged such that centers 101C to 105C can be aligned viewing in lamination direction 71A while insulating substrates 8, 59-1, 59-2 for connection, and double-sided wiring boards 4-1 and 4-2 are properly stacked in laminated body 71, as shown in FIG. 3A. As shown in FIG. 3G, centers 101C to 103C of fiducial marks 101 to 103 of insulating substrates 8-1, 59-1, and 59-2 for connection, and centers 104C and 105C of fiducial marks 104 and 105 of double-sided wiring boards 4-1 and 4-2 are image-recognized when these layers are stacked one on top of another. Insulating substrates 8, 59-1, and 59-2 for connection, and double-sided wiring boards 4-1 and 4-2 are aligned such that centers 101C-105C can be aligned in lamination direction 71A, thereby providing a multilayer wiring board composed of layers stacked precisely. After insulating substrates 8, 59-1, and 59-2 for connection, and double-sided wiring boards 4-1 and 4-2 are stacked as described above, fiducial marks 101 to 105 can be recognized by a device, such as an X-ray camera, for observing through metal. Misalignment of the stacked layers can be easily detected from a narrow field of vision, based on the relative positional relationship between fiducial marks 101 to 105. Such different fiducial marks for layers can prevent an error in the order of stacking.

In fiducial marks 101 to 105 according to the embodiment, the vias and wirings have a circular shape or circular arrangement, and may have other shapes to provide the same effects. Fiducial marks 104 and 105 can alternatively be formed on both surfaces of double-sided wiring boards 4-1 and 4-2. In this case, wirings 5-1 and 5-2 on double-sided wiring boards 4-1, 4-2, and the vias formed in insulating substrates 8-1, 59-1, and 59-2 for connection can be aligned on lower surfaces as well as the upper surfaces of double-sided wiring boards 4-1 and 4-2.

Fiducial marks 101-105 used in stacking each layer of laminated body 71 shown in FIG. 3A are often recognized with a camera, alternatively with reflected light, transmitted light, or X-ray according to circumstances. Fiducial marks 104, 105 formed on the upper surfaces of double-sided wiring boards 4-1, 4-2 are aligned with fiducial marks 101 and 102 implemented by the vias of insulating substrates 8-1, 59-1 for connection. Fiducial marks 104, 105 formed on the lower surfaces as well as the upper surfaces of double-sided wiring boards 4-1, 4-2 can be aligned with fiducial mark 102, 103 formed in insulating substrates 8-1, 59-2 for connection. This provides a multilayer wiring board composed of layers stacked precisely.

Fiducial marks 104 and 105 formed on the lower surfaces of double-sided wiring boards 4-1 and 4-2 can be recognized by a camera placed below laminated body 71 as well as a camera above laminated body 71. The vias formed in insulating substrates 8-1, 59-2 for connection, and fiducial marks 104, 105 formed in wirings 5-1, 5-2 on the lower surfaces of double-sided wiring boards 4-1, 4-2 can be captured with a camera placed above laminated body 71 through, e.g. a prism or a reflecting mirror.

In order to align wirings 5-1, 5-2 on the lower surfaces of double-sided wiring boards 4-1 and 4-2 with the vias in insulating substrates 8-1, 59-1, and 59-2 for connection, through-holes aligned with centers 104C and 105C of fiducial marks 104 and 105 formed on the lower surfaces of double-sided wiring boards 4-1, 4-2 are formed in double-sided wiring boards 4-1 and 4-2; then these through-holes are aligned with fiducial marks 101, 102, and 103 formed in insulating substrates 8-1, 59-1, and 59-2 for connection. Any of these methods can align wirings 5-1, 5-2 formed on double-sided wiring boards 4-1 and 4-2 with vias 7-1, 16-1, and 16-2 formed in insulating substrates 8-1, 59-1, and 59-2 for connection, thereby providing a multilayer wiring board having layers stacked precisely.

As described above, multilayer wiring board 1 includes at least double-sided wiring board 4, insulating substrate 59, vias 16, outermost wiring 9, and fiducial marks 101 and 104. Double-sided wiring board 4 includes insulating board 51, wirings 5 provided on the upper surface of insulating board 51 and made of conductive foil, and wirings 5 provided on the lower surface of insulating board 51 and made of conductive foil. Insulating substrate 59 has through-holes 62 formed therein and is stacked on double-sided wiring board 4 such that the lower surface of insulating substrate 59 is situated on the upper surface of insulating board 51, and that wirings 5 are embedded in insulating substrate 59. Each of vias 16 is formed in respective one of through-holes 62 in insulating substrate 59. Outermost wiring 9 is formed on the upper surface of insulating board 51. Fiducial mark 104 is formed on double-sided wiring board 4 in order to position double-sided wiring board 4. Fiducial mark 101 is formed in insulating substrate 59 in order to position insulating substrate 59. One via 16 out of vias 16 is connected with outer most wiring 9 and one wiring 5 out of wirings 5. Fiducial mark 104 includes at least one wiring 5 out of wirings 5. Fiducial mark 101 contains at least one via 16 out of vias 16.

The via 16 of fiducial mark 101 is located on circle 101B.

Multilayer wiring board 1 may further include insulating substrate 8, vias 7, and fiducial mark 102. Insulating substrate 8 has through-holes 6 therein and stacked on double-sided wiring board 4 such that the upper surface of insulating substrate 8 is situated on the lower surface of double-sided wiring board 4, and that wirings 5 are embedded in insulating substrate 8. Vias 7 are formed by filling through-holes 6 of insulating substrate 8 with conductive paste. Fiducial mark 102 includes at least one via 7 out of vias 7. Double-sided wiring board 4, insulating substrate 59, and insulating substrate 8 are stacked in lamination direction 71A. Viewing in lamination direction 71A, the at least one via 7 of fiducial mark 102 is located on circle 102B which is concentric with circle 101B and which has a diameter different from that of circle 101B.

Multilayer wiring board 1 may include fiducial mark 105 on double-sided wiring board 4 in order to position double-sided wiring board 4. Fiducial mark 105 includes at least one wiring 5 out of wirings 5. Fiducial mark 104 has a shape or size different from that of fiducial mark 105.

Fiducial marks 104 and 105 have circular shapes. Viewing in lamination direction 71A, one fiducial mark 105 out of fiducial marks 104 and 105 has a diameter enclosing another fiducial mark 104 out of fiducial marks 104 and 105 in the circular shape of fiducial mark 105.

Double-sided wiring board 4 and insulating substrate 59 are positioned such that the upper surface of insulating board 51 of double-sided wiring boards 4 faces the lower surface of insulating substrate 59 in lamination direction 71A, one of fiducial marks 101 and 104 encloses another of fiducial marks 101 and 104 viewing in lamination direction 71A.

A method for temporarily fixing the stacked layers of laminated body 13 shown in FIG. 2I after being positioned will be described below. Double-sided wiring boards 4, insulating substrates 8 and 59 for connection, and outermost wiring substrates 58 are temporarily fixed to prevent misalignment during handling before the heating and pressing.

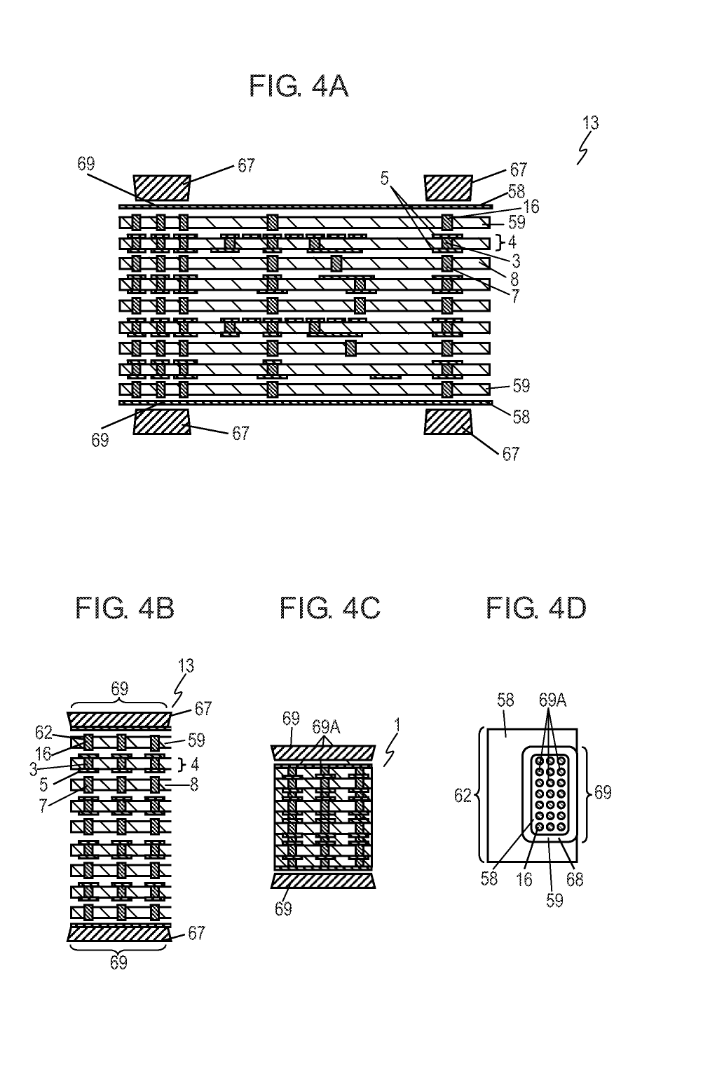

FIGS. 4A to 4C are sectional views multilayer wiring board 1 according to the embodiment for illustrating a method of manufacturing multilayer wiring board 1. FIGS. 4A to 4C particularly show a method of temporarily fixing double-sided wiring boards 4, insulating substrates 8, 59 for connection, and outermost wiring materials 58. In a method of temporarily fixing double-sided wiring boards 4, insulating substrates 8 and 59 for connection, and outermost wiring materials 58 in laminated body 13 is to partially weld insulating substrates 8 and 59 for connection to double-sided wiring boards 4 and outermost wiring materials 58. More specifically, as shown in FIG. 4A, after all layers of laminated body 13 shown in FIG. 2I are stacked, insulating substrates 8 and 59 for connection are partially welded to outermost wiring materials 58 and double-sided wiring boards 4 by heating and pressing a portion of laminated body 13 with heating tools 67, thereby positioning and fixing insulating substrates 8 and 59 for connection onto outermost wiring materials 58 and double-sided wiring boards 4.

The heat capacity of laminated body 13 increases as the number of layers of multilayer wiring board 1 increases, and may accordingly prevent insulating substrates 8 and 59 for connection from being firmly bonded to double-sided wiring board 4 which is located far away from the heating tools.

Heating tools 67 contact welding areas 69 on the surfaces of laminated body 13 to be heated and pressed. In order to allow the heat transmitting easily from heating tools 67 to insulating substrates 8 and 59 for connection and double-sided wiring boards 4, as shown in FIG. 4B, portions of laminated body 13 directly under heating tools 67 or sandwiched between welding areas 69 include through-holes 2, 6, and 62 filled with the conductive paste for forming vias 3, 7 and 16, and wirings 5 connected to these through-holes. Welding area 69 includes conductive pillars 69A each including vias 3, 7 and 16, wirings 5, and outermost wiring materials 58 aligned on a straight line. Conductive pillars 69A pass through insulating substrates 8, 59, and insulating board 51, thus extending from one outer surface of laminated body 13 to another outer surface thereof.

Welding areas 69 do not necessarily include wirings 5, however providing the same effects.

Then, as shown in FIG. 4C, welding areas 69 of laminated body 13 are heated and pressed with heating tools 67 to provide multilayer wiring board 1.

FIG. 4D is a top view of multilayer wiring board 1 shown in FIG. 4A, and shows welding areas 69 formed on both surfaces of laminated body 13. In welding areas 69 where insulating substrates 8 and 59 for connection are welded to double-sided wiring boards 4, outermost wiring materials 58 may preferably have no-wiring areas 68 where insulating substrates 59 for connection from outermost wiring materials 58. No-wiring areas 68 reduce a loss of heat transmitting from portions of outermost wiring materials 58 surrounded by no-wiring areas 68 to portions of outermost wiring materials 58 outside no-wiring areas 68. The area of welding area 69 may preferably be not smaller than the area of a portion of heating tool 67 contacting laminated body 13. This arrangement allows the heat of heating tools 67 to efficiently transmitting to laminated body 13.

Heating tools 67 are preferably capable of changing their temperature or pressure condition according to the thickness of laminated body 13.

In the processes for temporarily fixing shown in FIGS. 4A to 4C, all layers are welded to each other at once after being stacked. Alternatively, in multilayer wiring board 1 according to the embodiment, each of insulating substrate 8 or 59 for connection can be welded to each double-sided wiring board 4 starting from the bottom using heating tools 67. This operation allows the laminated body to have a small heat capacity than in the processes for welding all the layers to each other at once, hence allowing all layers to be temporarily fixed at precise positions. In this case, welding areas 69 having no-wiring areas 68 shown in FIG. 4D facilitates heat transmitting, accordingly providing multilayer wiring board 1 with layers stacked precisely.

In the case that double-sided wiring boards 4 are replaced by thicker wiring boards having four layers, the welding areas may be counterbored to have a small thickness locally to increasing thermal conductivity, thereby providing the same effects.

In the above-described example, welding area 69 provided in a portion of laminated body 13 is heated and pressed to temporarily fix the layers. The entire surfaces of insulating substrates 8 and 59 for connection or double-sided wiring boards 4 may be heated and pressed to temporarily fix the layers. This process increases the bonding strength of insulating substrates 8 and 59 for connection or double-sided wiring boards 4 during the temporary fixation after the stacking the layers, thereby providing multilayer wiring board 1 with layers stacked precisely.

As described above, laminated body 13 is prepared by partially welding insulating substrates 8 and 59 to insulating boards 51 of double-sided wiring boards 4 by heating and pressing welding area 69 with heating tools 67 to temporarily fix the layers.

In welding area 69, one of vias 7 and one of vias 3 are connected through one of wirings 5 to form conductive pillar 69A.

In welding area 69, insulating substrates 59 are exposed from outermost wirings 9 (outermost wiring materials 58).

The temporary fixation can be achieved by bonding the layers with an adhesive, instead of the heating and pressing.

One laminated body 13 is heated and pressed, as shown in FIG. 2J, but alternatively, plural laminated bodies 13 may be heated and pressed at once.

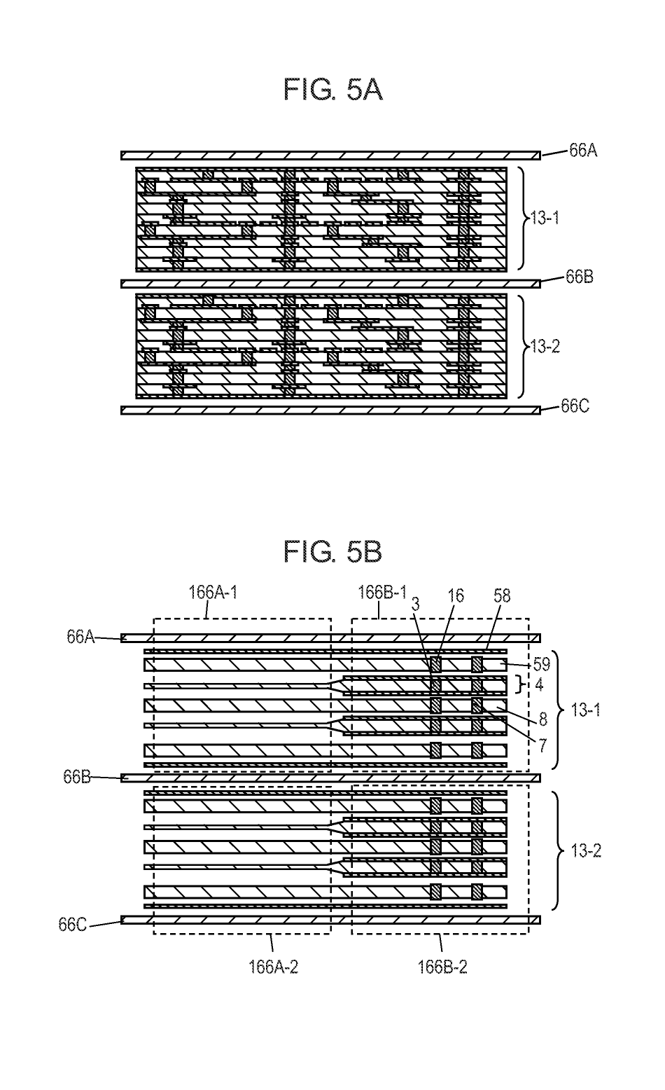

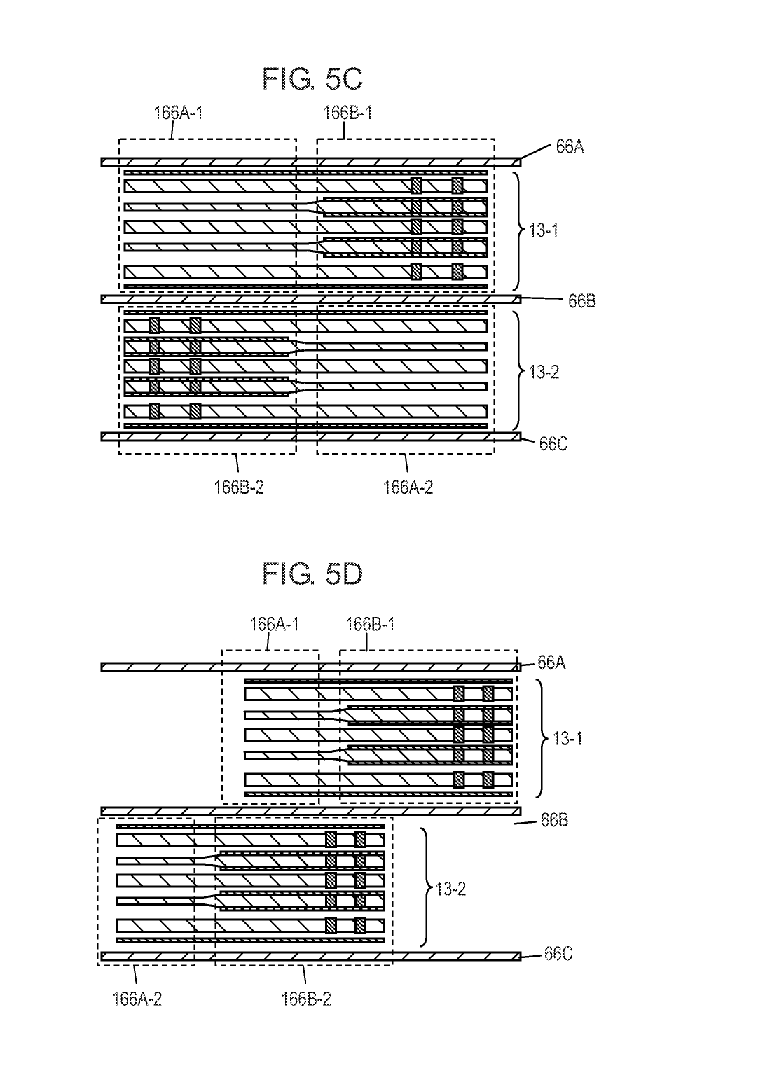

FIGS. 5A to 5D are sectional views of multilayer wiring board 1 according to the embodiment for illustrating of another method of manufacturing multilayer wiring board 1. Laminated bodies 13-1 and 13-2 are identical to laminated body 13. Rigid plate materials 66A to 66C, such as SUS plates, are stacked alternately with laminated bodies 13-1 and 13-2. Specifically, laminated body 13-1 is sandwiched between rigid plate materials 66A and 66B, whereas laminated body 13-2 is sandwiched between rigid plate materials 66B and 66C. In this situation, rigid plate materials 66A and 66C are compressed and heated, thereby providing multilayer wiring board 1 productively.

As shown in FIG. 5A, laminated bodies 13-1 and 13-2 (13) are stacked alternately across rigid plate materials 66A to 66C, and are heated and pressed. Similarly, three or more laminated bodies 13 can be stacked alternately across four or more rigid plate materials and heated and pressed, thereby providing multilayer wiring board 1 more productively.

However, when two laminated bodies 13-1 and 13-2 are stacked in the heating and pressing process, the bodies may be hardly pressed uniformly.

For example, as shown in FIG. 5B, laminated body 13-1 may include region 166B-1 having a large number of wirings 5 and vias 3, 7 and 16 and region 166A-1 having no or fewer vias 3, 7 and 16. Similarly, laminated body 13-2 includes region 166B-2 having a large number of wirings 5 and vias 3, 7 and 16, and region 166A-2 having no or fewer vias 3, 7 and 16. In these cases, each of laminated bodies 13-1 and 13-2 has a thickness varying locally. Region 166B-1 is thicker than region 166A-1, whereas region 166B-2 is thicker than region 166A-2. In this case, if laminated bodies 13-1 and 13-2 alternated with rigid plate materials 66A to 66C are heated and pressed, the pressure may not transmit to regions 166A-1 and 166A-2 having smaller thicknesses.

In the above case, in order to apply the pressure uniformly, laminated bodies 13-1 and 13-2 are stacked, as shown in FIG. 5C, so that region 166A-1 haces region 166B-2 across rigid plate material 66B, whereas region 166B-1 faces region 166A-2 across rigid plate material 66B. This arrangement allows laminated bodies 13-1 and 13-2 to be stacked and have a uniform thickness, hence allowing the pressure to transmit uniformly to laminated bodies 13-1 and 13-2 in the heating and pressing process.

As shown in FIG. 5D, laminated bodies 13-1 and 13-2 may be stacked while deviating such that region 166A-1 and 166B-2 of laminated bodies 13-1 and 13-2 face each other across rigid plate material 66B, region 166B-1 of laminated body 13-1 does not face laminated body 13-2 across rigid plate material 66B, and region 166A-2 of laminated body 13-2 does not face laminated body 13-1 across rigid plate material 66B. This arrangement allows the pressure to transmit uniformly to laminated bodies 13-1 and 13-2 in the heating and pressing process.

Considering the above, in laminated body 13 (multilayer wiring board 1) as a product, wirings 5 and vias 3, 7 and 16 are distributed as uniformly as possible such that their densities, numbers per unit volume, may not biased. While manufacturing multilayer wiring board 1, laminated bodies 13 as plural multilayer wiring boards 1 are formed in a single workpiece, and then separated from the workpiece. In a single workpiece, plural multilayer wiring boards 1 as products are connected to each other through joints which do not belong to multilayer wiring boards 1. When the densities of wirings 5 or vias 3, 7 and 16 are biased in these products, the bias in the entire workpiece can be eliminated by forming wirings 5 and vias 3, 7 and 16 in the joints. The joints are those portions which are to be discarded or do not belong to the products.

Test coupons for testing the degree of embedment of the resin of insulating substrates 8 and 59 for connection, and the electrical connection of vias 3, 7 and 16 after outermost wirings 9 are formed on multilayer wiring board 1 will be described below.

In multilayer wiring board 1 prepared by the processes shown in FIGS. 2A to 2K, all the layers are heated and pressed at once unlike the conventional multilayer wiring board 514 shown in FIGS. 7A to 7L including layers separately heated and pressed. Hence, even if multilayer wiring board 1 has voids due to the resin of insulating substrates 8 and 59 for connection not fully embedded around wirings 5, these voids can hardly be recognized from its appearance. Multilayer wiring board 1 according to the embodiment includes a test coupon to test the degree of embedment of the resin of insulating substrates 8 and 59 for connection. The test coupon is provided in the joints outside plural multilayer wiring boards 1 in a workpiece.

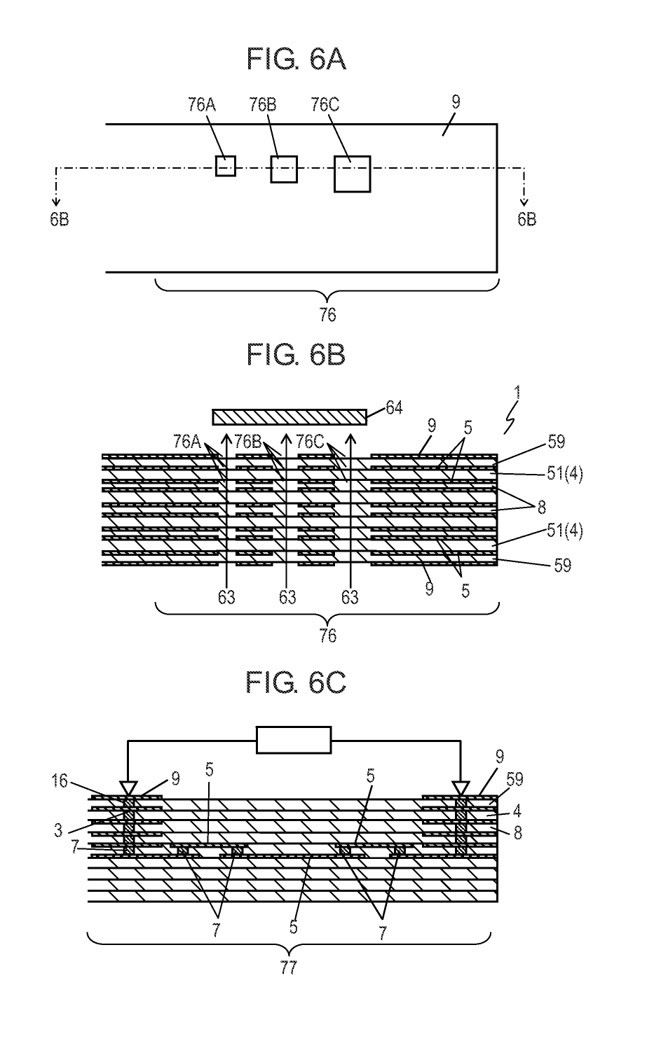

FIG. 6A is a top view of test coupon 76 for multilayer wiring boards 1. FIG. 6B is a sectional view of test coupon 76 at line 6B-6B shown in FIG. 6A. To examine the degree of embedment of the resin of insulating substrates 8 and 59 for connection, test coupon 76 is placed in a predetermined work size in which multilayer wiring boards 1 are connected to each other.

As shown in FIG. 6A, test coupon 76 includes no-wiring portions 76A to 76C having different areas. No-wiring portions 76A to 76C do not contain any of wiring materials 55 and 58 to form wirings 5 and 9 for all the layers. In no-wiring portions 76A to 76C, insulating substrates 8 and 59 for connection and insulating boards 51 of double-sided wiring boards 4 are exposed from wirings 5 and 9. After laminated body 13 is heated and pressed, light 63 is applied to no-wiring portions 76A to 76C of test coupon 76, and the transmittance of light 63 is detected with detector 64. If the resin is not firmly embedded around wirings 5, voids containing no resin are generated around wirings 5. The voids increase the transmittance of light 63 since the light does not attenuate in the voids. Detecting the transmittance of light 63 in no-wiring portions 76A to 76C having different areas from each other can determine how small space between wirings 5 the resin of insulating substrates 8 and 59 for connection can be embedded into. In other words, it can be determined that the resin is not fully embedded into spaces between wirings 5 which have smaller areas than a no-wiring portion out of no-wiring portions 76A to 76C exhibiting a large light transmittance.

It is determined whether the resin is fully embedded or not in actual products can be determined by setting the area of no-wiring portions 76A to 76C not including wirings 5 and 9 to be equal to no-wiring areas in actual products.

Test coupon 76 is preferably disposed in each product sheet instead of in each work size, so that the degree of embedment of the resin can be examined for each product, thereby improving the detection sensitivity.

It is determined whether the resin is fully embedded or not in finished multilayer wiring board 1 by thermal history, such as reflow.

As described above, test coupon 76 includes no-wiring portion 76A provided in one of the wirings 5 formed on the upper surface of double-sided wiring board 4, no-wiring portion 76A provided in one of the wirings 5 formed on the lower surface of double-sided wiring board 4, and no-wiring portion 76A provided in outermost wiring 9. The no-wiring portion 76A provided in the one of the wirings 5 formed on the lower surface of double-sided wiring board 4 (insulating board 51) is located directly under the no-wiring portion 76A provided in the one of the wirings 5 formed on the upper surface of double-sided wiring board 4 (insulating board 51). The no-wiring portion 76A provided in outermost wiring 9 is located directly above the no-wiring portion 76A provided in the one of the wirings 5 formed on the upper surface of double-sided wiring board 4.

Test coupon 76 may include no-wiring portion 76B provided in one of the wirings 5 formed on the upper surface of double-sided wiring board 4 (insulating board 51), no-wiring portion 76B provided in one of the wirings 5 formed on the lower surface of double-sided wiring board 4 (insulating board 51), and no-wiring portion 76B provided in outermost wiring 9. The no-wiring portion 76B provided in one of the wirings 5 formed on the lower surface of double-sided wiring board 4 (insulating board 51) is located directly under the no-wiring portion 76B provided in the one of the wirings 5 formed on the upper surface of double-sided wiring board 4 (insulating board 51). The no-wiring portion 76B provided in outermost wiring 9 is located directly above the no-wiring portion 76B provided in the one of the wirings 5 formed on the upper surface of double-sided wiring board 4 (insulating board 51). No-wiring portions 76B have areas different from those of no-wiring portions 76A.

Test coupon 76 may contain no-wiring portion 76C, provided in one of wirings 5 formed on the upper surface of double-sided wiring board 4 (insulating board 51), no-wiring portion 76C provided in one of the wirings 5 formed on the lower surface of double-sided wiring board 4 (insulating board 51), and no-wiring portion 76C provided in outermost wiring 9. The no-wiring portion 76C provided in the one of the wirings 5 formed on the lower surface of double-sided wiring board 4 (insulating board 51) is located directly under the no-wiring portion 76C provided in the one of the wirings 5 formed on the upper surface of double-sided wiring board 4 (insulating board 51). The no-wiring portion 76C provided in the outermost wiring 9 is located directly above the no-wiring portion 76C provided in the one of the wirings 5 formed on the upper surface of double-sided wiring board 4 (insulating board 51). No-wiring portions 76A to 76C have areas different from each other.

No-wiring portions 76A of test coupon 76 have the same area as no-wiring areas on the upper surface of the double-sided wiring board.

FIG. 6C is a sectional view of another test coupon 77 of multilayer wiring board 1. Test coupon 77 includes vias 3, 7, and 16 and wirings 5 which are connected in series between outermost wirings 9 formed on both surfaces of multilayer wiring board 1. The resistance of wirings 5 and vias 3, 7 and 16 can be measured through outermost wirings 9. This structure facilitates the evaluation of the via connection of a certain insulating substrate 8 for connection through which vias 7 and wirings 5 connected to vias 7 are connected in series with each other.

This approach is not limited to a specific layer, and is applicable to any other insulating substrates 8 for connection.

Test coupon 77 shown in FIG. 6C is one example, and any other circuit can be used as test coupon 77 as long as the circuit serially connects the vias 7 and wirings 5 formed in or on insulating substrates 8 for connection.

Multilayer wiring board 1 according to the embodiment can be manufactured productively by the two heating and pressing processes and the single circuit-forming process regardless of the number of the layers.

Multilayer wiring board 1 according to the embodiment may include those build-up layers on its outer surfaces which are connected by plating.

Two multilayer wiring boards 1 according to the embodiment may be connected to each other with insulating substrate 8 for connection disposed between siring boards 1, thereby providing a wiring board including a larger number of layers.

In the embodiment, terms, such as “upper surface”, “lower surface”, “above”, and “under”, indicating directions indicate relative directions depending only on the relative positional relationship of the components, such as the insulating substrates and the double-sided wiring boards, of the multilayer wiring board, and do not indicate absolute directions, such as a vertical direction.

### INDUSTRIAL APPLICABILITY

A multilayer wiring board according to the present invention has high connection reliability between its layers, and can be manufactured productively.

### REFERENCE MARKS IN THE DRAWINGS

3 Via (Third Via)
4 Double-Sided Wiring Board (First Double-Sided Wiring Board, Second Double-Sided Wiring Board)
5 Wiring (First Wiring, Second Wiring, Third Wiring, Fourth Wiring)
6 Through-Hole (Second Through-Hole)
7 Via (Second Via)
8 Insulating Substrate (Second Insulating Substrate)
9 Outermost Wiring
13 Laminated Body
16 Via (First Via)
51 Insulating Board (First Insulating Board, Second Insulating Board)
59 Insulating Substrate (First Insulating Substrate)
62 Through-Hole (First Through-Hole)
67 Heating Tool
69 Welding Area
71 Laminated Body
71A Lamination Direction
76 Test Coupon
76A No-Wiring Portion (First No-Wiring Portion, Second No-Wiring Portion, Third No-Wiring Portion)
76B No-Wiring Portion (Fourth No-Wiring Portion, Fifth No-Wiring Portion, Sixth No-Wiring Portion)
101 Fiducial Mark (Second Fiducial Mark)
102 Fiducial Mark (Third Fiducial Mark)
104 Fiducial Mark (First Fiducial Mark)
105 Fiducial Mark (Fourth Fiducial Mark)

1. A multilayer wiring board comprising:
a first double-sided wiring board including
a first insulating board,
a plurality of first wirings provided on an upper surface of the first insulating board and made of conductive foil, and
a plurality of second wirings provided on a lower surface of the first insulating board and made of conductive foil;
a first insulating substrate stacked on the first double-sided wiring board, the first insulating substrate having a lower surface situated on the upper surface of the first insulating board such that the first wirings are embedded in the first insulating substrate, the first insulating substrate having a plurality of first through-holes provided therein;
a plurality of first vias each of which is provided in respective one of the first through-holes of the first insulating substrate;
an outermost wiring formed on an upper surface of the first insulating substrate;
a first fiducial mark provided on the first double-sided wiring board to position the first double-sided wiring board;
a second fiducial mark provided on the first insulating substrate to position the first insulating substrate;
a second insulating substrate stacked on the first double-sided wiring board, the second insulating substrate having an upper surface situated on a lower surface of the first double-sided wiring board such that the second wirings are embedded into the second insulating substrate, the second insulating substrate having a plurality of second through-holes provided therein;
a plurality of second vias each of which is provided in respective one of the second through-holes of the second insulating substrate; and
a third fiducial mark provide on the second insulating substrate in order to position the second insulating substrate,
wherein one of the plurality of first vias is connected with the outermost wiring and one first wiring out of the plurality of first wirings,
wherein the first fiducial mark contains at least one wiring out of the plurality of first wirings and the plurality of second wirings,
wherein the second fiducial mark contains at least one first via out of the first vias,
wherein the at least one first via of the second fiducial mark is located on a first circle,
wherein the third fiducial mark contains at least one second via out of the plurality of second vias,
wherein the first double-sided wiring board, the first insulating substrate, and the second insulating substrate are stacked in a lamination direction; and
wherein, viewing in the lamination direction, the at least one second via of the third fiducial mark is located on a second circle which is concentric with the first circle and which has a diameter different from a diameter of the first circle.

2. (canceled)

3. (canceled)

4. The multilayer wiring board according to claim 1, further comprising:
a second double-sided wiring board including
a second insulating board having an upper surface situated on a lower surface of the second insulating substrate,
a plurality of third wirings provided on the upper surface of the second insulating board, the third wirings being made of conductive foil such that the plurality of third wirings are embedded into the second insulating substrate, and
a plurality of fourth wirings provided on a lower surface of the second insulating board, the fourth wirings being made of conductive foil; and
a fourth fiducial mark provided on the second double-sided wiring board to position the second double-sided wiring board,
wherein the fourth fiducial mark contains at least one wiring out of the plurality of third wirings and the plurality of fourth wirings, and
wherein the at least one wiring of the first fiducial mark has a different shape or size from the at least one wiring of the fourth fiducial mark.

5. The multilayer wiring board according to claim 4,
wherein the first double-sided wiring board, the second double-sided wiring board, the first insulating substrate, and the second insulating substrate are stacked in the lamination direction,
wherein the first fiducial mark has a circular shape,
wherein the fourth fiducial mark has a circular shape, and
wherein, viewing in the lamination direction, one fiducial mark of the first fiducial mark and the fourth fiducial mark has a diameter enclosing another fiducial mark of the first fiducial mark and the fourth fiducial mark.

6. The multilayer wiring board according to claim 1, further comprising a test coupon including:
a first no-wiring portion provided in one of the first wirings;
a second no-wiring portion provided in one of the second wirings and located directly under the first no-wiring portion; and
a third no-wiring portion provided in the outermost wiring and located directly above the first no-wiring portion.

7. The multilayer wiring board according to claim 6, wherein the test coupon further includes:
a fourth no-wiring portion provided in the one of the first wirings and having a different area from the first no-wiring portion;
a fifth no-wiring portion provided in the one of the second wirings and located directly under the fourth no-wiring portion, the fifth no-wiring portion having a different area from the second no-wiring portion; and
a sixth no-wiring portion provided in the outermost wiring and located directly above the fourth no-wiring portion, the sixth no-wiring portion having a different area from the third no-wiring portion.

8. The multilayer wiring board according to claim 6, wherein the first no-wiring portion of in the test coupon has an area identical to an area of a non-wiring portion on the upper surface of the double-sided wiring board.

9. A method of manufacturing a multilayer wiring board, the method comprising:
providing a double-sided wiring board which includes
an insulating board,
a plurality of first wirings provided on an upper surface of the insulating board and made of conductive foil,
a plurality of second wirings provided on a lower surface of the insulating board and made of conductive foil, and
a first fiducial mark containing at least one wiring out of the plurality of first wirings and the plurality of second wirings;
providing an insulating substrate having a plurality of through-holes provided therein;
forming a plurality of first vias in the through-holes of the insulating substrate, respectively such that the insulating substrate has a second fiducial mark containing at least one first via out of the plurality of first vias;
providing a laminated body which includes the insulating substrate, the double-sided wiring board, and an outermost wiring material provided on an upper surface of the insulating substrate, the outermost wiring material contacting one of the first vias, such that the upper surface of the insulating board faces a lower surface of the insulating substrate in a lamination direction;
heating and pressing to the laminated body; and
forming an outermost wiring connected to the one of the first vias by patterning the outermost wiring material,
wherein said providing the laminated body comprises positioning the double-sided wiring board and the insulating substrate such that the upper surface of the insulating board of the double-sided wiring board faces the lower surface of the insulating substrate in the lamination direction, and that one of the first fiducial mark and the second fiducial mark encloses another of the first fiducial mark and the second fiducial mark viewing in the lamination direction, and
wherein said heating and pressing to the laminated body comprises heating and pressing the laminated body such that the plurality of first wirings of the double-sided wiring board are embedded in the insulating substrate.

10. The method according to claim 9, wherein said providing the double-sided wiring board comprises:
laminating protective films on the upper surface and the lower surface of the insulating board;
forming through-holes in the insulating board having the protective films laminated thereon;
filling the through-holes with conductive paste;
removing the protective films after said filling the through-holes with the conductive paste;
stacking a first wiring material and a second wiring material on the upper surface and the lower surface of the insulating substrate, respectively, after said removing the protective films; and
forming the plurality of first wirings and the plurality of second wirings by patterning the first wiring material and the second wiring material.

11. The method according to claim 9,
wherein the laminated body has a welding area, and
wherein said providing the laminated body comprises temporally fixing a portion of the insulating substrate to the insulating board of the double-sided wiring by welding the portion of the insulating substrate to the insulating board of the double-sided wiring board by heating and pressing the welding area with a heating tool.

12. The method according to claim 11,
wherein the double-sided wiring board further includes a second via passing through the insulating board and being connected to one of the plurality of first wirings and to one of the plurality of second wirings, and
wherein in the welding area, one first via of the plurality of first vias is connected with the second via through one of the plurality of first wirings.

13. The method according to claim 11, wherein in the welding area, the insulating substrate is exposed from the outermost wiring.

14. The method according to claim 9,
wherein the double-sided wiring board further includes:
a first no-wiring portion provided in one of the plurality of first wirings; and
a second no-wiring portion provided in one of the plurality of second wirings and located directly under the first no-wiring portion,
wherein said method further comprises:
forming a third no-wiring portion in the outermost wiring, the third no-wiring portion being located directly above the first no-wiring portion; and
detecting a light transmittance of the laminated body by irradiating laminated body with light.

15. The method according to claim 14,
wherein the first no-wiring portion, the second no-wiring portion, and the third no-wiring portion constitute a test coupon, and
wherein said detecting the light transmittance of the laminated body comprises detecting the light transmittance of the laminated body by irradiating the test coupon of the laminated body with the light.
